(19) United States
(12) Patent Application Publication
(10) Pub. No.: US 2013/0147027 A1
(43) Pub. Date: Jun. 13, 2013

(54) SEMICONDUCTOR PACKAGE

(71) Applicant: Job Ha, Gyunggi-do (KR)

(72) Inventor: Job Ha, Gyunggi-do (KR)

(73) Assignee: SAMSUNG ELECTRO-MECHANICS CO., LTD., Gyunggi-do (KR)

(21) Appl. No.: 13/403,867

(22) Filed: Feb. 23, 2012

(30) Foreign Application Priority Data
Dec. 7, 2011 (KR) 1020110130415

(51) Int. Cl. H01L 23/34

(52) U.S. Cl. 257/706; 257/E23.08

(57) ABSTRACT

Disclosed herein is a semiconductor package.

According to a preferred embodiment of the present invention, there is provided a semiconductor package, including: a first substrate having a first wiring pattern formed therein; a first semiconductor device mounted above the first substrate by being contacted with the first substrate; a second substrate having a second wiring pattern formed therein; a third semiconductor device mounted above the first semiconductor device and contacted with a lower portion of the second substrate; and a third substrate positioned between the first semiconductor device and the third semiconductor device and having a third wiring pattern including at least one upper electrode and lower electrode protruding outwardly, the lower electrode being contacted with the first semiconductor device and the upper electrode being contacted with the third semiconductor device.

### CROSS REFERENCE TO RELATED APPLICATION

This application claims the benefit of Korean Patent Application No. 10-2011-0130415, filed on Dec. 7, 2011, entitled “Semiconductor Device Package”, which is hereby incorporated by reference in its entirety into this application.

### BACKGROUND OF THE INVENTION

1. Technical Field

The present invention relates to a semiconductor package.

2. Description of the Related Art

With the development of power electronic industries, miniaturization and high densification of power semiconductor modules have been of an increasing importance. For this reason, the attempt to decrease sizes of semiconductor devices themselves and the miniaturization of modules themselves have been important subjects. With the trend of small form factor in electronic devices, high density and high mountability of a package, which is a core element of the electronic devices, have emerged as important factors. Therefore, various structures of semiconductor packages have been manufactured by using several types of substrates such as a lead frame, a printed circuit board, a circuit film, and the like. Recently, as solutions to achieve the reduction in size and high integration in semiconductor packages, there have been supposed various structures of packages, such as a chip scale package manufactured in a size close to chip size, a multi chip package (MCP) in which a plurality of chips or packages are mounted, a system in package, a package using a composite substrate, packages stacked on each other, and the like. (Korean Patent Laid-Open Publication No 10-2009-0093163).

These types of power semiconductor packages are manufactured with a structure in which a plurality of semiconductor devices are soldered and attached on a single substrate using an insulating substrate and a housing case is bonded thereon. Thereafter, wire-bonding or soldering is used to connect between the semiconductor devices and the substrate and between the substrate and terminals inserted in the housing. Here, the semiconductor devices are protected by an insulating resin such as silicon gel.

However, more and relatively wider spaces are required in order to parallel-arrange the semiconductor devices on the single substrate. Furthermore, heat radiation can not be effectively performed since a heat radiating plate is disposed only below the semiconductor package.

### SUMMARY OF THE INVENTION

The present invention has been made in an effort to provide a semiconductor package capable of being miniaturized by the structure in which semiconductor devices are stacked.

The present invention has been also made in an effort to provide a semiconductor package allowing series connection and parallel connection.

The present invention has been also made in an effort to provide a semiconductor package having improved heat radiation performance.

According to a preferred embodiment of the present invention, there is provided a semiconductor package, including: a first substrate having a first wiring pattern formed therein; a first semiconductor device mounted above the first substrate by being contacted with the first substrate; a second substrate having a second wiring pattern formed therein; a third semiconductor device mounted above the first semiconductor device and contacted with a lower portion of the second substrate; and a third substrate positioned between the first semiconductor device and the third semiconductor device and having a third wiring pattern including at least one upper electrode and lower electrode protruding outwardly, the lower electrode being contacted with the first semiconductor device and the upper electrode being contacted with the third semiconductor device.

The third substrate may have an insulating film formed above and below the third wiring pattern, the upper electrode and the lower electrode being exposed by the insulating film.

The first semiconductor device may be contacted with the upper electrode of the third substrate and the third semiconductor device is contacted with the lower electrode of the third substrate, thereby to allow the first semiconductor device and the third semiconductor device to be connected to each other in series.

The semiconductor package may further include a second semiconductor device spaced apart from the first semiconductor device and mounted above the first substrate by being contacted with the first substrate.

The first semiconductor device and the second semiconductor device may be connected to each other in parallel by being contacted with a plurality of the lower electrodes of the third substrate, respectively.

The semiconductor package may further include a housing surrounding the first substrate and the second substrate so as to shut off an inner space formed between the first substrate and the second substrate from the outside.

The semiconductor package may further include an insulating resin filled in an inner space of the housing.

The semiconductor package may further include a damper positioned between an upper housing and a lower housing of the housing to form a space in which the first semiconductor device and the third semiconductor device are stacked among the first substrate, the second substrate, and the third substrate.

The damper may be formed of an elastic member.

The semiconductor package may further include a clip contacted with and electrically connected to at least one of the first substrate, the second substrate, and the third substrate.

The clip may be formed of a conductive metal having elasticity.

The semiconductor package may further include a first heat radiating plate formed below the first substrate.

The semiconductor package may further include a second heat radiating plate formed above the second substrate.

### BRIEF DESCRIPTION OF THE DRAWINGS

FIG. 1 is an exemplified view showing a semiconductor package according to a preferred embodiment of the present invention;

FIG. 2 is an exemplified view showing the bonding of semiconductor devices in the semiconductor package according to the preferred embodiment of the present invention;

FIG. 3 is an exemplified view showing electrodes of a third substrate according to the preferred embodiment of the present invention; and

FIG. 4 is an exemplified view showing a semiconductor package according to another preferred embodiment of the present invention.

### DESCRIPTION OF THE PREFERRED EMBODIMENTS

Various objects, advantages and features of the invention will become apparent from the following description of preferred embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description and preferred embodiments taken in conjunction with the accompanying drawings. In the specification, in adding reference numerals to components throughout the drawings, it is to be noted that like reference numerals designate like components even though components are shown in different drawings.

Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, semiconductor packages according to preferred embodiments of the present invention will be described in detail with reference to the accompanying drawings.

FIG. 1 is an exemplified view showing a semiconductor package according to a preferred embodiment of the present invention;

Referring to FIG. 1, a semiconductor package 100 may include a first substrate 110, a second substrate 120, a third substrate 130, a first semiconductor device 141, a second semiconductor device 142, a third semiconductor device 143, a fourth semiconductor device 144, and a housing 150.

The first substrate 110 may have a first wiring pattern (not shown) formed thereon.

Examples of the first substrate 110 may include a printed circuit board (PCB), a ceramic substrate, an insulated metal substrate (IMS), a pre-molding substrate, and a direct bonded copper (DBC) substrate. Also, the first substrate 110 may be a conductive substrate provided by a lead frame. Also, the first substrate 110 may be made of metal-based nitrides or a ceramic material. For example, the first substrate 110 may be formed by including aluminum nitrides, silicon nitrides, aluminum oxides, or beryllium oxides. Theses are for examples of the first substrate 110, and a material for the first substrate 110 is not limited thereto.

This first substrate 110 may have the first wiring pattern (not shown) formed thereon. The first wiring pattern (not shown) may be formed by conventional wiring patterning methods. For example, the wiring pattern (not shown) may be formed by chemical vapor deposition (CVD), physical vapor deposition (PVD), electro-plating, or electroless plating. The first wiring pattern (not shown) may be formed of a conductive metal. For example, the first wiring pattern (not shown) may be formed of aluminum, aluminum alloy, copper, copper alloy, nickel, gold, or an alloy thereof.

The first substrate 110 may have a first insulating film (not shown) for protecting the first wiring pattern (not shown). The first insulating film (not shown) may be formed on the entire region of the first substrate 110, excluding portions that are contacted with and electrically connected to the first semiconductor device 141 and the second semiconductor device 142.

The other surface of the first substrate 110, which faces one surface in which the first wiring pattern (not shown) is formed, may be bonded to an inside surface of a lower housing 151.

The second substrate 120 may have a second wiring pattern (not shown) formed in one surface of thereof.

The second substrate 120 may also be formed of the same material as the first substrate 110. Also, the second wiring pattern (not shown) formed in the second substrate 120 may be formed in the same manner as the first wiring pattern (not shown). The other surface of the second substrate 120, which faces one surface in which the second wiring pattern (not shown) is formed, may be bonded to an inside surface of an upper housing 152.

The second substrate 120 may have a second insulating film (not shown) for protecting the second wiring pattern (not shown). The second insulating film (not shown) may be formed in the entire region of the second substrate 120, excluding portions that are contacted with and electrically connected to the third semiconductor device 143 and the fourth semiconductor device 144.

The third substrate 130 may have a third wiring pattern formed therein.

The third substrate 130 may also be formed of the same material as the first substrate 110. Also, the third wiring pattern (131) of the third substrate 130 may be formed in the same manner as the first wiring pattern (not shown).

Also, the third substrate 130 may have an upper electrode 133 and a lower electrode 134 formed therein. The upper electrode 133 and the lower electrode 134 may be electrically connected to the third wiring pattern 131, and may protrude more outwardly than the second substrate 120. The upper electrode 133 and the lower electrode 134 are contacted with and electrically connected to the first semiconductor device 141 to the fourth semiconductor device 144.

The third substrate 130 may have a third insulating film (132) for protecting the third wiring pattern 131. The third insulating film 132 may be formed in the entire region of the third substrate excluding the outwardly protruding upper and lower electrodes 133 and 134.

The first semiconductor device 141 to the fourth semiconductor device 144 each may be a power device or a control device. For example, the first semiconductor device 141 and the second semiconductor device each may be a power device. Also, the third semiconductor device 143 and the fourth semiconductor device 144 each may be a control device.

The first semiconductor device 141 and the second semiconductor device 142 may be mounted above the first substrate 110. Also, the first semiconductor device 141 and the second semiconductor device 142 may be electrically connected to each other by the first substrate 110. Here, the first substrate 110 and the first semiconductor device 141, and the first substrate 110 and the second semiconductor device 142 may be electrically connected by a non-soldering method. The first semiconductor device 141 and the second semiconductor device 142 may be contacted with the first substrate due to the pressure thereabove. In other words, the first semiconductor device 141 and the second semiconductor device 142 may be contacted with the first substrate 110 due to the pressure applied at the time of coupling the housing, while they are mounted on the first wiring pattern (not shown) of the first substrate 110. Through this manner, the first substrate 110 may be electrically connected to the first semiconductor device 141 and the second device 142.

In addition, the third substrate 130 may be mounted above the first semiconductor device 141 and the second semiconductor device 142. Here, the first semiconductor device 141 and the second semiconductor device 142 may be respectively contacted with the lower electrode 134 of the third substrate 130, thereby achieving electric connection therebetween. Here, the third substrate 130 are may be electrically connected to the first semiconductor device 141 and the second semiconductor device 142 by a non-soldering method.

The third semiconductor device 143 and the fourth semiconductor device 144 may be mounted above the third substrate 130. Here, the third semiconductor device 143 and the fourth semiconductor device 144 may be contacted with the upper electrode 133 of the third substrate 130, thereby achieving electric connection therebetween. Here, the third substrate 130 may be electrically connected to the third semiconductor device 143 and the fourth semiconductor device 144 by a non-soldering method.

The second substrate 120 may be mounted above the third semiconductor device 143 and the fourth semiconductor device 144. Here, the semiconductor device 143 and the fourth semiconductor device 144 may be electrically connected to the second substrate 120 by a non-soldering method. In other words, the third semiconductor device 143 and the fourth semiconductor device 144 may be contacted with the second wiring pattern of the second substrate 120, thereby achieving electric connection therebetween.

The first semiconductor device 141 to the fourth semiconductor device 144 may be electrically connected to each other by the first substrate 110 to the third substrate 130 having the wiring patterns in a non-soldering method. In addition, a structure in which the first semiconductor device 141 to the fourth semiconductor device 144 are stacked can be formed by the third substrate 130 having the upper electrode 133 and the lower electrode 134. In addition, the semiconductor devices stacked above and below may be connected to each other in series by the upper electrode 133 and the lower electrode 134 of the third substrate 130. For example, as shown in FIG. 1, the first semiconductor device 141 and the second semiconductor device 142 may be connected to each other in series by the third substrate 130 and through the upper electrode 133 and the lower electrode 134 of the third substrate 130. In addition, semiconductor devices mounted on the same substrate may be connected in parallel by the first substrate 110 and the second substrate 120. For example, as shown in FIG. 1, the first semiconductor device 141 and the second semiconductor device 142 may be connected in parallel by the first substrate 110. The third semiconductor device 143 and the fourth semiconductor device 144 may be connected in parallel by the second substrate 120.

The housing 150 may have a structure that surrounds the first substrate 110 and the second substrate 120 so that an inner space formed between the first substrate 110 and the second substrate 120 is shut off from the outside. The housing 150 may be formed of an insulating material. An inside of the housing 150 may be filled with an insulating resin 160 for protecting structures positioned inside the housing 150.

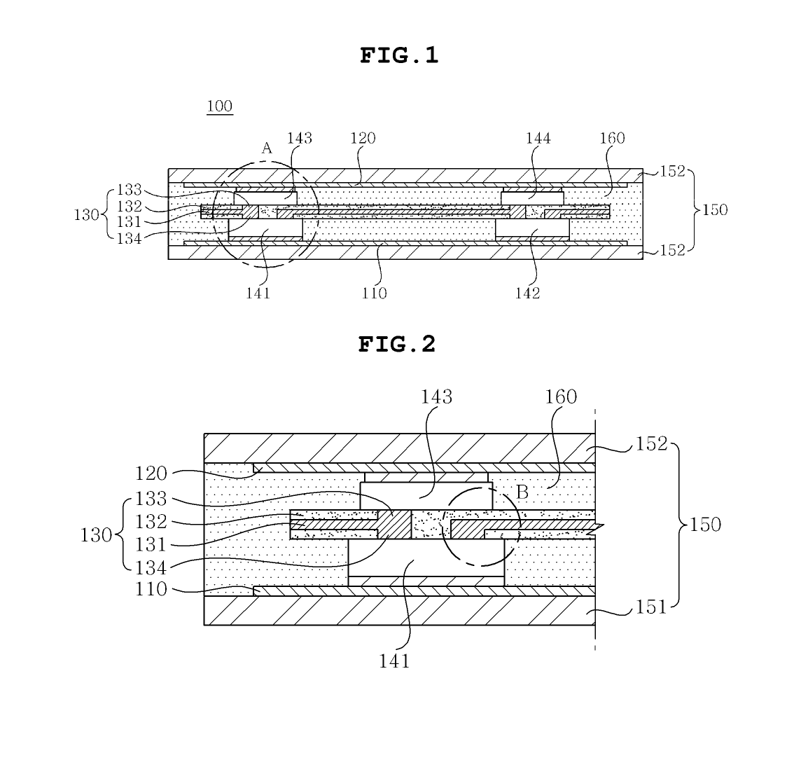

FIG. 2 is an exemplified view showing the bonding of semiconductor devices in the semiconductor package according to the preferred embodiment of the present invention.

FIG. 2 shows an enlarged image of Region A in FIG. 1.

Referring to FIG. 2, the first semiconductor device 141 may be mounted above the first substrate 110. In addition, the third substrate 130 may be mounted above the first semiconductor device 141. Here, the first semiconductor device 141 may be contacted with the lower electrode 134 of the third substrate 130. The first semiconductor device 141 may be a power device, for example, an insulated gate bipolar transistor (IGBT). A collector and an emitter of the first semiconductor device 141 may be contacted with a first lower electrode 134 and a second lower electrode 134 of the third substrate, respectively. Here, the first lower electrode 134 and the second lower electrode 134 may be formed such that they are electrically insulated from each other by the third wiring pattern 131. In addition, a gate of the first semiconductor device 141 may be contacted with the first wiring pattern (not shown) of the first substrate 110.

The third semiconductor device 143 may be mounted above the third substrate 130. In addition, the second substrate 120 may be mounted above the third semiconductor device 143. Here, the third semiconductor device 143 may be contacted with the upper electrode 133 of the third substrate 130. The third semiconductor device 143 may be a control device, for example a diode. A cathode of the third semiconductor device 143 may be contacted with the upper electrode 133 of the third substrate 130. In addition, an anode of the third semiconductor device 143 may be contacted with the second wiring pattern (not shown) of the second substrate 120.

In such a stacking structure of the first semiconductor device 141 and the third semiconductor device 143, the first semiconductor device 141 and the third semiconductor device 143 may be connected to each other in series by the third substrate 130.

Referring to FIG. 1 and the second lower electrode 134 of FIG. 2, it can be seen that the first semiconductor device 141 may be contacted with one side of the second lower electrode 134 and the second semiconductor device 142 may be connected to the other side of the second lower electrode 134. Therefore, the first semiconductor device 141 and the second semiconductor device 142 may be connected in parallel by the third substrate 130.

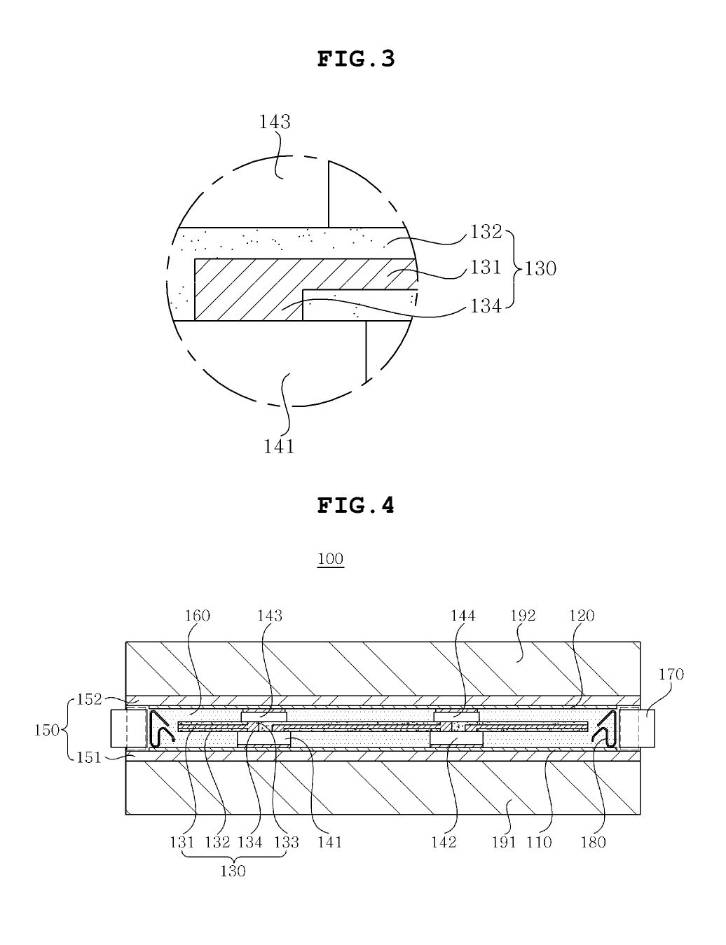

FIG. 3 is an exemplified view showing electrodes of the third substrate according to the preferred embodiment of the present invention.

FIG. 3 shows an enlarged image of Region B in FIG. 2.

Referring to FIG. 3, the third substrate 130 may include electrodes 133 and 134 protruding outwardly. These electrodes 133 and 134 protruding outwardly may be contacted with the semiconductor devices 141 and 143, thereby achieving electric connection with the semiconductor devices 141 and 143.

The third substrate 130 may have the third insulating film 132 formed in an upper portion and a lower portion thereof. Here, the third insulating film 132 may be formed in the third substrate 130 such that the electrodes 133 and 134 are exposed to the outside.

Only the lower electrode 134 of the third substrate 130, which protrudes downwardly, is shown in FIG. 3, but the protruding direction, position, and number of electrodes of the third substrate 130 may be easily changed by those skilled in the art.

FIG. 4 is an exemplified view showing a semiconductor package according to another preferred embodiment of the present invention.

Referring to FIG. 4, a semiconductor package 100 may include a first substrate 110, a second substrate 120, a third substrate 130, a first semiconductor device 141, a second semiconductor device 142, a third semiconductor device 143, a fourth semiconductor device 144, a housing 150, clips 180, dampers 170, a first heat radiating plate 191, and a second heat radiating plate 192.

The first substrate 110 may have a first wiring pattern (not shown) formed therein.

Examples of the first substrate 110 may include a printed circuit board (PCB), a ceramic substrate, an insulated metal substrate (IMS), a pre-molding substrate, and a direct bonded copper (DBC) substrate. Also, the first substrate 110 may be a conductive substrate provided by a lead frame. Also, the first substrate 110 may be made of metal-based nitrides or a ceramic material. For example, the first substrate 110 may be formed by including aluminum nitrides, silicon nitrides, aluminum oxides, or beryllium oxides. Theses are examples of the first substrate 110, and a material for the first substrate 110 is not limited thereto.

This first substrate 110 may have the first wiring pattern (not shown) formed therein. The first wiring pattern (not shown) may be formed by conventional wiring patterning methods. For example, the wiring pattern (not shown) may be formed by chemical vapor deposition (CVD), physical vapor deposition (PVD), electro-plating, or electroless plating. The first wiring pattern (not shown) may be formed of a conductive metal. For example, the first wiring pattern (not shown) may be formed of aluminum, aluminum alloy, copper, copper alloy, nickel, gold, or an alloy thereof. The other surface of the first substrate 110, which faces one surface of the first substrate 110 in which the first wiring pattern (not shown) is formed, may be bonded to an inside surface of a lower housing 151.

The second substrate 120 may have a second wiring pattern (not shown) formed in one surface of thereof.

The second substrate 120 may also be formed of the same material as the first substrate 110. Also, the second wiring pattern (not shown) formed in the second substrate 120 may be formed in the same manner as the first wiring pattern (not shown). The other surface of the second substrate 120, which faces one surface of the second substrate 120 in which the second wiring pattern (not shown) is formed, may be bonded to an inside surface of an upper housing 152.

The third substrate 130 may have a third wiring pattern formed therein.

The third substrate 130 may also be formed of the same material as the first substrate 110. Also, the third wiring pattern (131) of the third substrate 130 may be formed in the same manner as the first wiring pattern (not shown).

Also, the third substrate 130 may have an upper electrode 133 and a lower electrode 134 formed therein. The upper electrode 133 and the lower electrode 134 may be electrically connected to the third wiring pattern 131, and may protrude more outwardly than the second substrate 120. The upper electrode 133 and the lower electrode 134 are contacted with and electrically connected to the first semiconductor device 141 to the fourth semiconductor device 144.

The first substrate 110, the second substrate 120, and the third substrate 130 each may have an insulating film for protecting wiring patterns thereof. The insulating films may be respectively formed at regions excluding portions in which the first semiconductor device 141 to the fourth semiconductor device 144 are contacted with and electrically connected to each other. For example, the insulating film of the third substrate 130 may be formed to expose the upper electrode 133 and the lower electrode 134 which are contacted with the first semiconductor device 141 to the fourth semiconductor device 144.

The first semiconductor device 141 to the fourth semiconductor device 144 may be power devices or control devices. For example, the first semiconductor device 141 and the second semiconductor device each may be a power device. Also, the third semiconductor device 143 and the fourth semiconductor device 144 each may be a control device.

The first semiconductor device 141 and the second semiconductor device 142 may be electrically connected to the first substrate 110. Here, the first substrate 110 and the first semiconductor device 141, and the first substrate 110 and the second semiconductor device 142 may be electrically connected by a non-soldering method.

The third substrate 130 may be mounted above the third semiconductor device 143 and the fourth semiconductor device 144. Here, the first semiconductor device 141 and the second semiconductor device 142 may be contacted with the lower electrodes 134 of the third substrate 130, respectively, thereby achieving electric connection therebetween.

The third semiconductor device 143 and the fourth semiconductor device 144 may be mounted above the third substrate 130. Here, the third semiconductor device 143 and the fourth semiconductor device 144 may be contacted with the upper electrode 133 of the third substrate 130, thereby achieving electric connection therebetween.

The second substrate 120 may be mounted above the third semiconductor device 143 and the fourth semiconductor device 144. Here, the semiconductor device 143 and the fourth semiconductor device 144 may be electrically connected to the second substrate 120 by a non-soldering method.

As such, the first semiconductor device 141 to the fourth semiconductor device 144 may be electrically connected to each other by the first substrate 110 to the third substrate 130 having wiring patterns by a non-soldering method. In addition, a structure in which the first semiconductor device 141 to the fourth semiconductor device 144 are stacked can be formed by the third substrate 130 having the upper electrode 133 and the lower electrode 134. For example, as shown in FIG. 1, the first semiconductor device 141 and the third semiconductor device 143 may be stacked by the third substrate 130. Also, the second semiconductor device 142 and the fourth semiconductor device 144 may be stacked by the third substrate 130.

In addition, the semiconductor devices stacked above and below may be connected to each other in series by the upper electrode 133 and the lower electrode 134 of the third substrate 130. For example, as shown in FIG. 1, the first semiconductor device 141 and the second semiconductor device 142 may be connected to each other in series by the third substrate 130 through the upper electrode 133 and the lower electrode 134. In addition, semiconductor devices mounted on the same substrate may be connected in parallel by the first substrate 110 and the second substrate 120.

The housing 150 may have a structure that surrounds the first substrate 110 and the second substrate 120 so that an inner space formed between the first substrate 110 and the second substrate 120 is shut off from the outside. The housing 150 may be formed of an insulating material. An inside of the housing 150 may be filled with an insulating resin 160 for protecting structures positioned inside the housing 150.

The dampers 170 may be formed at both sides of the housing 150. The dampers 170 may be positioned between the upper housing 152 and the lower housing 151. Also, the dampers 170 may be positioned between the first substrate 110 and the second substrate 120. As such, a space between the first substrate 110 and the second substrate 120 may be formed by the thus formed dampers 170. As such, the space is formed between the first substrate 110 and the second substrate 120 by the dampers 170, thereby minimizing physical impact between the structures, which may cause defects when the structures are stacked within the semiconductor package 100. In other words, a sufficient space is formed within the housing 150 by the dampers, and thus, the structures within the housing 150 can be stably stacked. The damper 170 may be formed of an elastic member.

The clips 180 may be contacted with and electrically connected to at least one of the first substrate 110, the second substrate 120, and the third substrate 130. In other words, the clips 180 may electrically connect any two of the first substrate 110, the second substrate 120, and the third substrate 130 to each other. The clip 180 may be formed of a conductive metal.

The first heat radiating plate 191 may be formed below the lower housing 151. The first heat radiating plate 191 may be a heat sink of radiating heat. The heat sink may be formed of metal, metal nitride, ceramic resin, or a combination thereof. The first heat radiating plate 191 may be attached by an adhesive agent. Here, the adhesive agent may be formed of a material having excellent heat conductivity. For example, the adhesive agent may be formed of solder, metal epoxy, metal paste, resin-based epoxy, or an adhesive tape having excellent heat resistance.

The second heat radiating plate 192 may be formed above the upper housing 152. The second heat radiating plate 192 may be a heat sink that radiates heat. Also, the second heat radiating plate 192 may be attached by an adhesive agent. Here, the adhesive agent may be formed of a material having excellent heat conductivity.

As such, the semiconductor package according to the preferred embodiments of the present invention can be miniaturized by the structure in which the semiconductors are stacked. Further, in the semiconductor package according to the preferred embodiments of the present invention, the semiconductor devices are connected to each other by first substrate to the third substrate, and thus, serial connection and parallel connection thereof can be all achieved. Further, the semiconductor package according to the preferred embodiments of the present invention can have improved heat radiation performance since heat radiating plates are formed both above and below the housing.

The semiconductor package according to the preferred embodiments of the present invention can be miniaturized by the structure in which the semiconductors are stacked.

In the semiconductor package according to the preferred embodiments of the present invention, the semiconductor devices are connected to each other by a first substrate to a third substrate, and thus, serial connection and parallel connection thereof can all be achieved.

The semiconductor package according to the preferred embodiments of the present invention can have improved heat radiation performance since heat radiating plates are formed both above and below the housing.

Although the preferred embodiments of the present invention have been disclosed for illustrative purposes, they are for specifically explaining the present invention and thus a semiconductor package according to the present invention is not limited thereto, and those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A semiconductor package, comprising:
a first substrate having a first wiring pattern formed therein;
a first semiconductor device mounted above the first substrate by being contacted with the first substrate;
a second substrate having a second wiring pattern formed therein;
a third semiconductor device mounted above the first semiconductor device and contacted with a lower portion of the second substrate; and
a third substrate positioned between the first semiconductor device and the third semiconductor device and having a third wiring pattern including at least one upper electrode and lower electrode protruding outwardly, the lower electrode being contacted with the first semiconductor device and the upper electrode being contacted with the third semiconductor device.

2. The semiconductor package as set forth in claim 1, wherein the third substrate has an insulating film formed above and below the third wiring pattern, the upper electrode and the lower electrode being exposed by the insulating film.

3. The semiconductor package as set forth in claim 1, wherein the first semiconductor device is contacted with the upper electrode of the third substrate and the third semiconductor device is contacted with the lower electrode of the third substrate, thereby to allow the first semiconductor device and the third semiconductor device to be connected to each other in series.

4. The semiconductor package as set forth in claim 1, further comprising a second semiconductor device spaced apart from the first semiconductor device and mounted above the first substrate by being contacted with the first substrate.

5. The semiconductor package as set forth in claim 4, wherein the first semiconductor device and the second semiconductor device are connected to each other in parallel by being contacted with a plurality of the lower electrodes of the third substrate, respectively.

6. The semiconductor package as set forth in claim 1, further comprising a housing surrounding the first substrate and the second substrate so as to shut off an inner space formed between the first substrate and the second substrate from the outside.

7. The semiconductor package as set forth in claim 6, further comprising an insulating resin filled in an inner space of the housing.

8. The semiconductor package as set forth in claim 6, further comprising a damper positioned between an upper housing and a lower housing of the housing to form a space in which the first semiconductor device and the third semiconductor device are stacked among the first substrate, the second substrate, and the third substrate.

9. The semiconductor package as set forth in claim 8, wherein the damper is formed of an elastic member.

10. The semiconductor package as set forth in claim 1, further comprising a clip contacted with and electrically connected to at least one of the first substrate, the second substrate, and the third substrate.

11. The semiconductor package as set forth in claim 10, wherein the clip is formed of a conductive metal having elasticity.

12. The semiconductor package as set forth in claim 1, further comprising a first heat radiating plate formed below the first substrate.

13. The semiconductor package as set forth in claim 1, further comprising a second heat radiating plate formed above the second substrate.
